(19) United States
(12) Patent Application Publication
(10) Pub. No.: US 2025/0102538 A1
(43) Pub. Date: Mar. 27, 2025

(54) TEST SOCKET FOR IC TESTING AND MANUFACTURING METHOD THEREOF

(71) Applicant: He Chou Technology INC., Hsinchu City (TW)

(72) Inventors: WEI-BEEN YU, Hsinchu City (TW); SHAO-CHUN TSENG, Hsinchu City (TW)

(21) Appl. No.: 18/677,854

(22) Filed: May 29, 2024

(30) Foreign Application Priority Data
Sep. 21, 2023 (TW) 112136098

(51) Int. Cl. G01R 1/04; G01R 3/00

(52) U.S. Cl. CPC G01R 1/0441; G01R 3/00

(57) ABSTRACT

A test socket for integrated circuit (IC) testing is provided and comprises an insulating support structure and multiple conductive columns. The insulating support structure features multiple through-holes designed to accommodate the conductive columns. Parts of the conductive columns are embedded within the insulating support structure and extend through these through-holes to establish electrical connections for IC testing. The conductive columns are elastic, allowing them to accommodate variations caused by warpage of the IC packaging and the tolerances in BGA solder ball sizes. Additionally, the insulating support structure incorporates multiple grooves located next to the through-holes, where parts of the conductive columns are embedded, enhancing the fixation strength of the conductive columns to the insulating support structure. Furthermore, the test socket includes anti-short-circuit brackets positioned beside the conductive columns to prevent them from contacting each other and causing short circuits. The invention also provides a method for manufacturing this test socket.

### FIELD OF THE DISCLOSURE

The present invention relates to the field of integrated circuit (IC) testing, specifically to a test socket for IC testing and methods for its manufacture.

### BACKGROUND OF THE INVENTION

Integrated Circuit testing (IC testing) is a critical process in the electronics industry, ensuring the functionality and reliability of ICs before they are integrated into various electronic devices. A common approach to IC testing involves the use of test sockets that provide electrical connections between the IC and the test circuitry. These connections are typically made using conductive columns (also known as pogo pins) embedded within an insulating support of the test socket. The insulating support is usually designed with through-holes that allow the conductive columns to pass through and establish the necessary electrical connections. Conductive columns are generally composed of conductive particles and a flexible material, such as silicone, to provide the flexibility needed to accommodate ICs of varying sizes and shapes. However, securing the conductive columns to the insulating support robustly is a challenge in the design and manufacture of test sockets. The fixation strength can affect the durability and lifetime of the test socket, as well as the stability of the electrical connections during IC testing. Moreover, the design of the test socket must also consider the prevention of short circuits. There is a risk of the conductive columns touching each other and causing a short circuit when pressed down during IC testing.

Current test socket designs often mold the conductive columns by stamper method, which is limited by the mold release method and does not allow for increased height of the conductive columns, reducing the available flexibility. If the IC has variations in solder ball size tolerances during packaging process or temperature-induced warping, issues can be raised during the use of the test socket, leading to ineffective or unstable electrical contacts between the test IC and the testing circuitry. For instance, technologies disclosed in U.S. Pat. No. 7,726,984 B2, U.S. Pat. No. 9,263,817 B2, and TW1800143 B use a harder material, such as Polyimide, to support a softer material, such as Silicone, in forming the elastic conductors. However, due to the different materials, the fixation strength between the elastic conductors and the insulating support is insufficient, leading to the conductors detaching from the insulating support issues in long-term usage. Similarly, U.S. Pat. No. 9,488,675 B2 and KR100972662B1 disclose technologies where the insulating support and the elastic conductors are integrally formed from silicone. This structure is mostly created by stamper method, but this process cannot completely remove the residual mold metal particles from the surface during the curing of the conductive gel, presenting risks of electrical leakage and ionic migration. Additionally, because the material of the support is relatively soft, its lifetime is also shorter.

Thus, the aforementioned deficiencies are significant issues worthy of consideration and resolution by those of ordinary skill in the art.

### SUMMARY OF THE INVENTION

In order to address the issues outlined above, the objective of the present invention is to provide a test socket for IC testing and a method for manufacturing the same. Based on this objective and other aims, the invention provides an enhanced test socket for IC testing that strengthens the fixation of the conductive columns to the insulating support structure, thereby increasing the lifetime of the test socket and the stability of the electrical connections during testing. To achieve these and other goals, the test socket comprises an insulating support structure equipped with multiple through-holes and several conductive columns, where a portion of the conductive columns is embedded in the insulating support structure and extends through these through-holes.

In the aforementioned test socket, the insulating support structure comprises multiple grooves located adjacent to the through-holes, and portions of the conductive columns are embedded in these grooves. The conductive columns have a first part located below the insulating support structure and a second part located above the insulating support structure. The insulating support structure may comprise a hard support and a soft support, the soft support located on the upper surface of the hard support, and the hard support layer being harder than the conductive columns.

The hard support may be composed of multiple layers of different materials. The grooves can be located within the hard support. The test socket may also include multiple anti-short-circuit brackets located beside the conductive columns, made of insulating material. The height of these anti-short-circuit brackets can range from 0.7 to 4 times the height of the second part of the conductive columns.

The height of the first part of the conductive columns can range from 10 to 100 micrometers, and the height of the second part can be 2 to 10 times the height of the first part. The diameter ratio of the first part to the second part can range from 5/6 to 6/5. The insulating support structure may be made from materials selected from a group consisting of polyimide, PCB materials, and ceramic materials. The conductive columns can be composed of conductive particles and silicone, where the conductive particles are selected from a group consisting of metal powder, metal alloy powder, graphite powder, conductive compounds, and conductive plastics.

The present invention provides a method for manufacturing a test socket for integrated circuit (IC) testing. The method includes the following steps:

First, forming a layered structure that comprises a first sacrificial layer, an insulating support layer, and a second sacrificial layer.

Next, forming multiple through-holes in this layered structure and creating multiple grooves within the through-holes of the insulating support layer.

Then, filling the through-holes with a conductive gel to form multiple conductive columns.

Finally, removing the first and second sacrificial layers.

In some embodiments, the method also includes placing multiple anti-short circuit brackets adjacent to the conductive columns. In other embodiments, the method includes forming a layered structure that comprises a first sacrificial layer, an insulating support layer, an anti-short circuit layer, and a second sacrificial layer.

In certain embodiments, the removal of the first and second sacrificial layers involves stripping these layers or dissolving them using a solvent. The solvent dissolution of the first and second sacrificial layers includes methods such as hydrolysis or acid-base dissolution.

In some embodiments, the insulating support layer comprises a hard support layer and a soft support layer, the soft support layer located above the hard support layer. In other embodiments, the hard support layer comprises multiple layers composed of different materials.

In some embodiments, the materials for the first and second sacrificial layers are chosen from a group consisting of positive photoresist, polyimide, polyvinyl alcohol (PVA), and silicone. In other embodiments, the thickness of the second sacrificial layer is 2 to 10 times that of the first sacrificial layer.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1 illustrates a partial cross-sectional view of an embodiment of the test socket for IC testing according to the present invention.

FIGS. 2A to 2D show the diameter ratios of the first and second parts of different conductive columns.

FIG. 3 depicts another embodiment of the test socket for IC testing according to the invention.

FIG. 4 is a flowchart of the manufacturing process for the test socket shown in FIG. 1.

FIGS. 5A to 5E illustrate the intermediate products corresponding to each step of the process shown in FIG. 4.

FIG. 6 is a flowchart of the manufacturing process for the test socket shown in FIG. 3.

FIGS. 7A to 7F illustrate the intermediate products corresponding to each step of the process shown in FIG. 6.

FIG. 8A shows another embodiment of the test socket in one of the manufacturing process step.

FIG. 8B illustrates another embodiment of the test socket for IC testing according to the present invention.

### DESCRIPTION OF THE PREFERRED EMBODIMENTS

Refer to FIG. 1, which illustrates a partial cross-sectional view of an embodiment of the test socket for IC testing according to the present invention. In this embodiment, test socket 100 is used for IC testing and comprises an insulating support structure 110 and multiple conductive columns 120. The insulating support structure 110 has multiple through-holes 112 that are designed to accommodate the conductive columns 120. These conductive columns 120 are partially embedded in the insulating support structure 110 and extend through the through-holes 112 to establish electrical connections for IC testing.

The conductive columns 120 are elastic, allowing them to adapt to variations caused by warpage of the IC packaging and the tolerance of BGA solder ball sizes. In this embodiment, conductive columns 120 consist of conductive particles 127 and a flexible material 128, such as silicone. The conductive columns 120 comprise two parts: a first part 122 located below the insulating support structure 110, and a second part 124 located above the insulating support structure 110. This structure of conductive columns 120 effectively bridges the gap between the IC and the test circuitry, facilitating the transmission of electrical signals during testing.

In addition to through-holes 112, the insulating support structure 110 also features multiple grooves 114 located adjacent to the through-holes 112. These grooves 114 provide a space for a protruding part 126 embedded as a portion of the conductive columns 120, thereby enhancing the fixation strength as well as the durability. of the conductive columns 120 to the insulating support structure 110. It implies that grooves 114 play a crucial structural role within the insulating support structure 110. The additional support by conductive columns 120, allowing the conductive columns 120 have more fixation strength and able to withstand various pressures and stresses during IC testing. Additionally, because the protruding part 126 of conductive columns 120 is embedded in grooves 114, this also increases the contact area between the conductive columns 120 and the insulating support structure 110, thereby enhancing its overall durability.

In summary, the test socket 100 of this embodiment includes its insulating support structure 110 and conductive columns 120, providing a robust and flexible solution for IC testing as well as enhancing the lifetime of test socket 100.

Conductive columns 120 provide the electrical connection between the IC and the test circuit. The conductive particles 127 within these conductive columns 120 can be made from various materials, including metal powders, metal alloy powders, graphite powders, conductive compounds, and conductive plastics. The choice of materials for conductive particles 127 can affect the conductivity, durability, and cost of test socket 100. Moreover, the first part 122 of conductive columns 120 is positioned below insulating support structure 110, with a designed height ranging from 10 to 100 micrometers. This height is tailored to accommodate the process tolerances of the pads on the test circuit, ensuring stable and reliable electrical connections during testing. The second part 124 of conductive columns 120 is positioned above insulating support structure 110, with a height that is 2 to 10 times that of the first part 122. The increased height of the second part 124 is designed to accommodate IC process tolerances and temperature deformations, further enhancing the functionality of test socket 100.

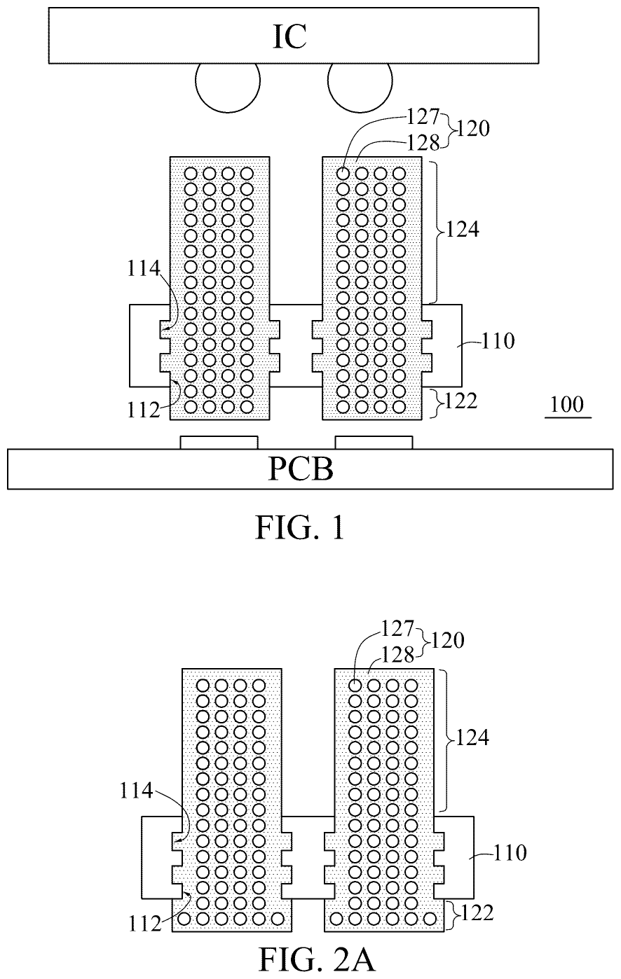

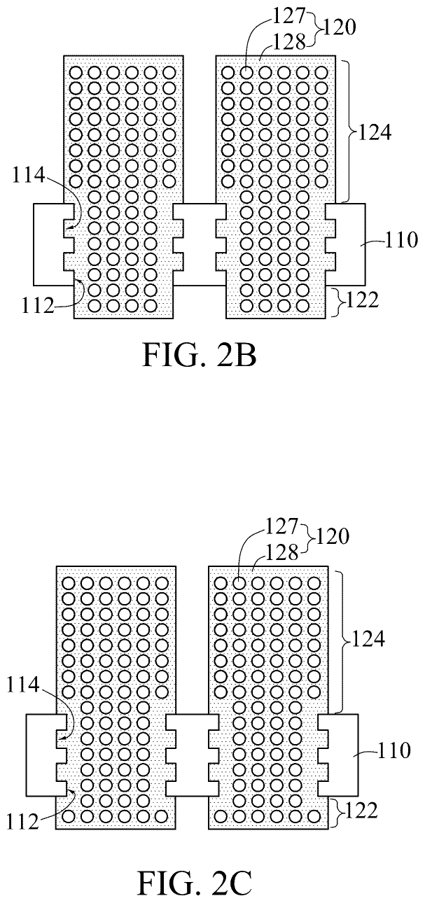

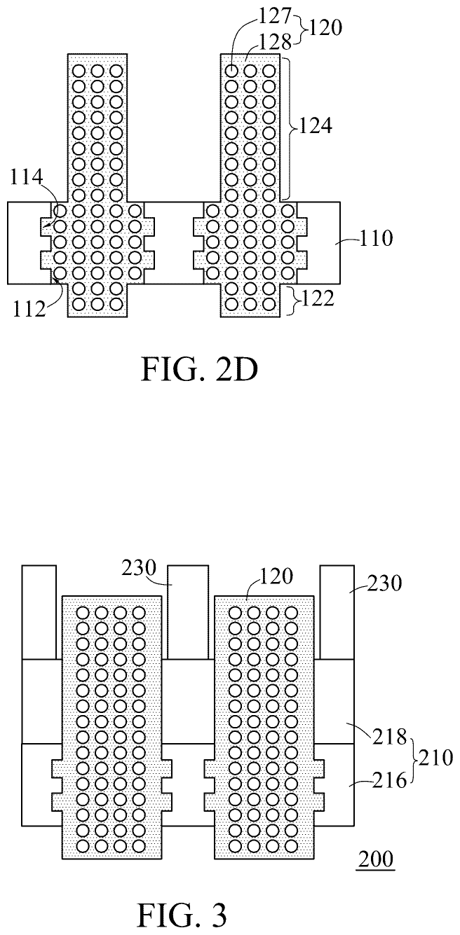

In this embodiment, the diameter ratio between the first part 122 and the second part 124 of the conductive columns ranges from 5/6 to 6/5. This ratio can be adjusted based on the specific requirements of the IC and the test circuit, providing greater flexibility in the design of the test socket. The following are some examples:
1. Refer to FIG. 2A, where the diameter ratio of the first part 122 to the second part 124 is 1.2:1, and the diameter of conductive columns 120 embedded in the insulating support structure 110 is the same as that of the first part 122. This design can be used when a larger contact area is needed at the bottom of the conductive columns 120 to adhere more securely to the test circuit board.
2. Refer to FIG. 2B, where the diameter ratio of the first part 122 to the second part 124 is 1:1.2, and the diameter of the conductive columns 120 embedded in the insulating support structure 110 is the same as that of the second part 124. This design can be used when a larger contact area is needed at the top of the conductive columns 120 to adhere more securely to the IC.
3. Refer to FIG. 2C, where the diameter ratio of the first part 122 to the second part 124 is 1:1, and the diameter of the conductive columns 120 embedded in the insulating support structure 110 is greater than that of both the first part 122 and the second part 124. This design can be used when a larger contact area is needed for both the IC and the test circuit, for example, when handling larger or more robust components.
4. Refer to FIG. 2D, where the diameter ratio of the first part 122 to the second part 124 is 1:1, and the diameter of the conductive columns 120 embedded in the insulating support structure 110 is less than that of both the first part 122 and the second part 124. This design can be used when smaller contact areas are needed for both the IC and the test circuit, for example, when dealing with smaller BGA solder ball pitches or more delicate components.

These examples illustrate the flexibility of test socket 100 in adapting to various requirements of the IC and the test circuit. By adjusting the diameter ratio of the first part 122 to the second part 124 of the conductive columns 120, as well as the diameter of the conductive columns 120 embedded in the insulating support structure 110, test socket 100 can be customized according to the specific requirements of different testing scenarios.

Refer to FIG. 3, which illustrates another embodiment of the test socket for IC testing according to the present invention. In this embodiment, the insulating support structure 210 of test socket 200 is composed of two distinct supports: a hard support 216 and a soft support 218. The soft support 218 is located on the upper surface of the hard support 216. The hard support 216 forms the base of the insulating support structure 210, characterized by its greater hardness compared to the hardness of the conductive columns 120, providing robust and durable support for the conductive columns 120.

On the other hand, the soft support 218 is positioned on the upper surface of the hard support 216. The placement of the soft support 218 provides a flexible and adaptable interface for the conductive columns 120, and providing the necessary flexibility for the conductive columns 120, while also contributing to the overall durability of test socket 200. The materials of the soft support 218 can be selected from various types of elastomers or flexible polymers. For instance, silicone might be an appropriate choice due to its excellent thermal stability and electrical insulation properties. Other possible materials could include thermoplastic elastomers, polyurethane rubber, or polyvinyl chloride. T. Note that the choice of materials will also depend on other factors such as the specific requirements of the IC testing process, cost considerations, and potential compatibility issues with other components of test socket 200.

In summary, the hard support 216 and the soft support 218 form a composite insulating support structure 210, which combines the sturdiness of the hard support 216 with the flexibility of the soft support 218. This composite structure enhances the Fixation strength of the conductive columns 120 to the insulating support structure 210, reducing the likelihood of the conductive columns 120 detaching from the insulating support structure 210 during testing. Moreover, the composite structure also enhance the overall durability and lifetime of the test socket, making it a reliable and cost-effective solution for IC testing.

By the way, in this embodiment, test socket 200 further comprises anti-short-circuit brackets 230. These brackets are positioned adjacent to conductive columns 120 and are made from insulating material. The primary function of these anti-short-circuit brackets 230 is to prevent the short circuit issue of conductive columns 120 by contacting each other. This is particularly important during IC testing when the conductive columns 120 are pressed downward, as the downward pressure may cause the columns to bend and touch, resulting in a short circuit. By placing anti-short-circuit brackets 230 next to the conductive columns 120, the risk of short circuits is effectively mitigated, enhancing the reliability and safety of test socket 200 during testing. Additionally, the anti-short-circuit brackets 230 also prevent excessive downward pressure on the solder balls, which could damage the conductive socket.

The anti-short-circuit brackets 230 are made of insulating material.

In one embodiment, the height of the anti-short-circuit brackets 230 is designed to be between 0.7 to 4 times the height of the second part 124 of the conductive columns 120 to ensures that the anti-short-circuit brackets 230 are tall enough to prevent the conductive columns 120 from touching each other, yet low enough not to interfere with the movement and deformation of the conductive columns 120 during testing.

Additionally, in this embodiment, grooves 214 (not shown in FIG. 3) are formed in the hard support 216 of the insulating support structure 210. The structure and function of grooves 214 are similar to those of grooves 114 in FIG. 1, and thus are not further elaborated here.

In summary, incorporating anti-short-circuit brackets 230 as part of test socket 200 enhances the safety and reliability of test socket 200 during IC testing and prevent the conductive columns 120 from contacting each other

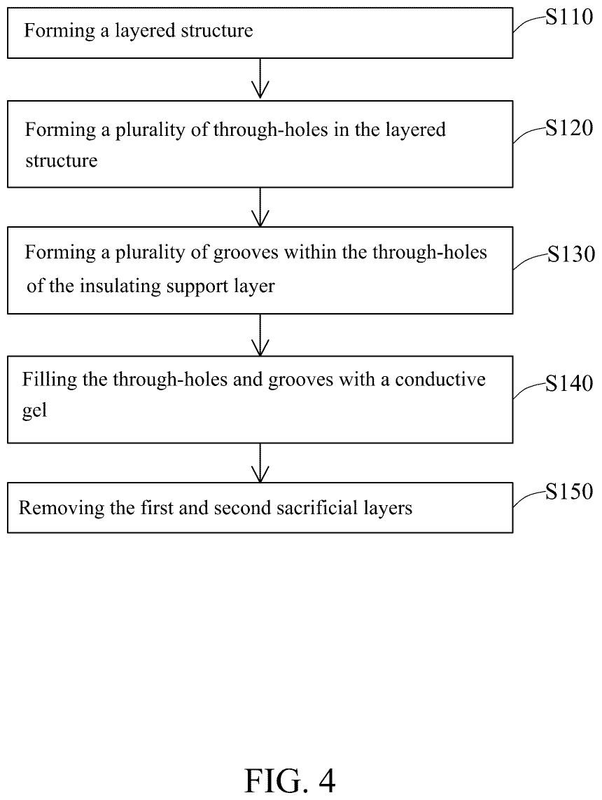

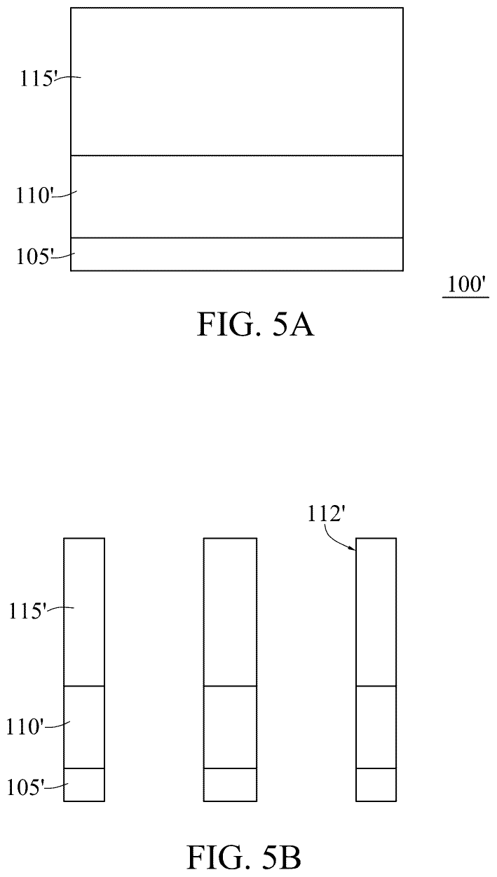

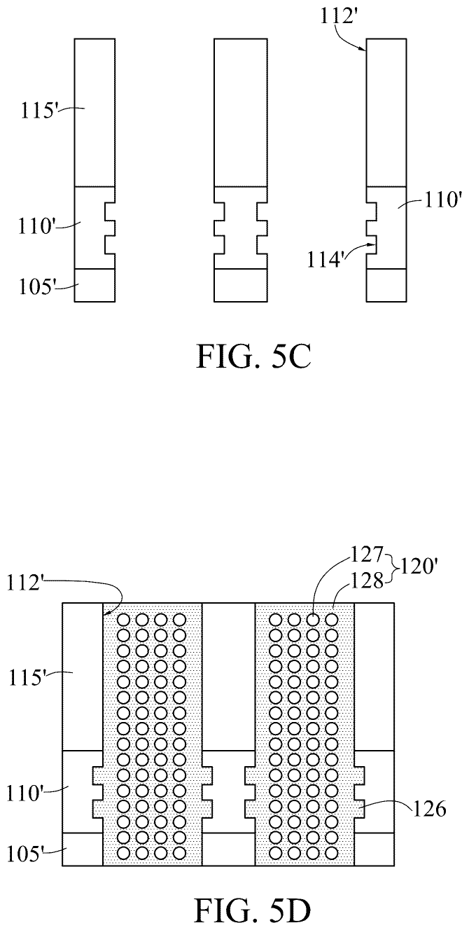

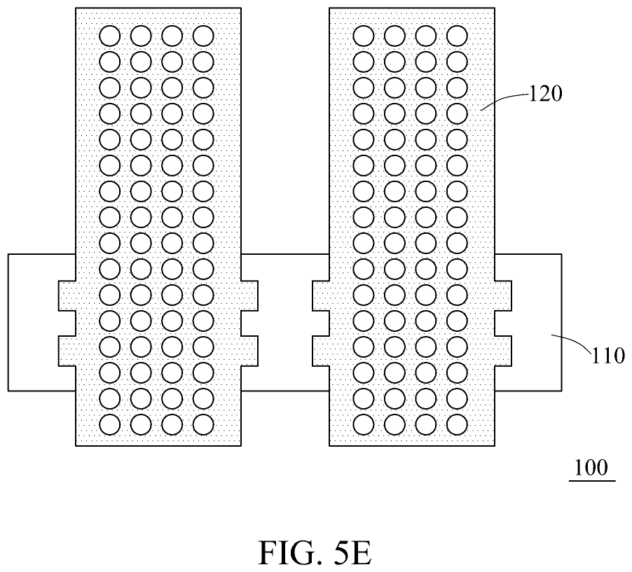

Refer to FIG. 1, FIGS. 4 and 5A-5E, where the manufacturing process for test socket 100 involves several steps. Initially, as shown in step S110 of FIG. 5A, forming a layered structure 100′. This layered structure 100′ comprises a first sacrificial layer 105′, an insulating support layer 110′, and a second sacrificial layer 115′. The first and second sacrificial layers 105′, 115′ serve as temporary structures that aid in forming the insulating support structure 110 and the conductive columns 120. In the embodiment, the materials for the first sacrificial layer 105′ and the second sacrificial layer 115′ are selected from a group consisting of positive photoresist, polyimide, polyvinyl alcohol (PVA), and silicone. These material can be removed in subsequent steps by dissolution or lifting off, depending on the specific conditions and requirements of the process.

Next, step S120 is performed. As illustrated in FIG. 5B, forming a plurality of through-holes in the layered structure. Forming of these through-holes 112′ involves precise drilling or etching techniques to ensure their size and placement accurately correspond to the size and placement of the conductive columns 120.

Next, step S130 is executed (as shown in FIG. 5C), forming a plurality of grooves 114′ within the through-holes of the insulating support layer 110′ around the boundaries of the through-holes 112′. The design of these grooves 114′ is intended to further enhance the Fixation strength of the conductive columns 120 to the insulating support layer 110′. These grooves 114′ are formed by subtractive processes such as etching or carving, allowing parts of the conductive columns 120 to be embedded within them. This increases the contact area between the conductive columns 120 and the insulating support structure 110, reducing the likelihood of the conductive columns 120 detaching from the insulating support structure 110 during testing, thereby enhancing the overall reliability of test socket 100.

Next, step S140 (as shown in FIG. 5D), filling the through-holes 112′ and grooves with a conductive gel 120′ to form a plurality of conductive columns. This conductive gel 120′, consisting of conductive particles 127 and a flexible material 128 (such as silicone), solidifies to form the conductive columns 120. The conductive columns 120 extend through the through-holes 112′, with part of the columns, the protruding part 126, embedded in the grooves 114′ of the insulating support layer. The embedding of parts of the conductive columns 120 into grooves 114′ enhances their Fixation strength to the insulating support structure 110. This increases the contact area between the conductive columns 120 and the insulating support structure 110, reducing the likelihood of the conductive columns 120 detaching from the insulating support structure 110 during testing, thereby enhancing the overall reliability of test socket 100.

Next, step S150 (as shown in FIG. 5E), removing the first and second sacrificial layers 105′ and 115′. This removal can be accomplished by various methods, such as lifting away the first and second sacrificial layers 105′, 115′ or using a solvent to dissolve them. The removal of the first sacrificial layer 105′ and the second sacrificial layer 115′ exposes the insulating support structure 110 and the conductive columns 120, completing test socket 100.

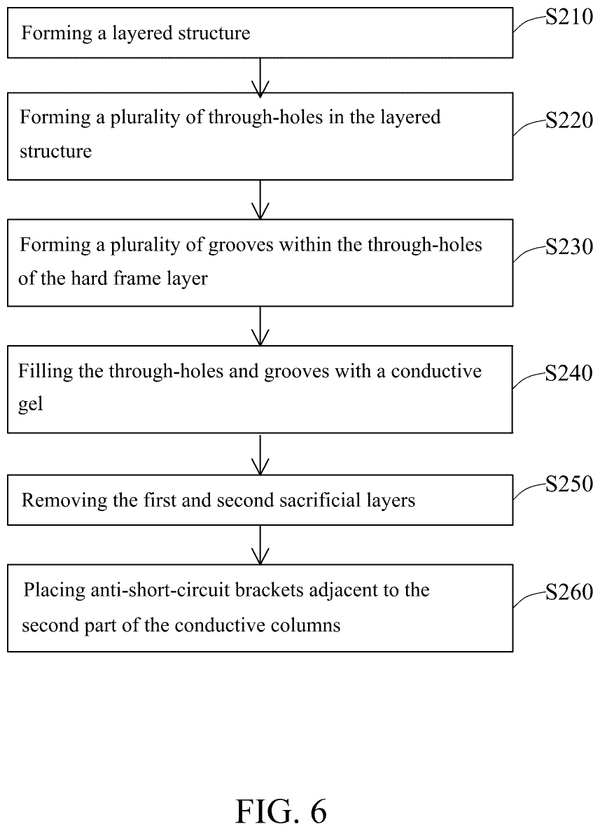

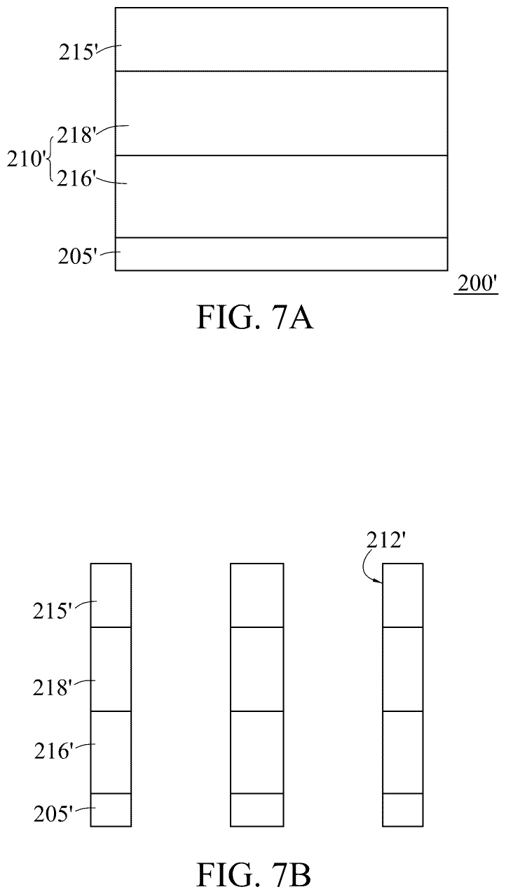

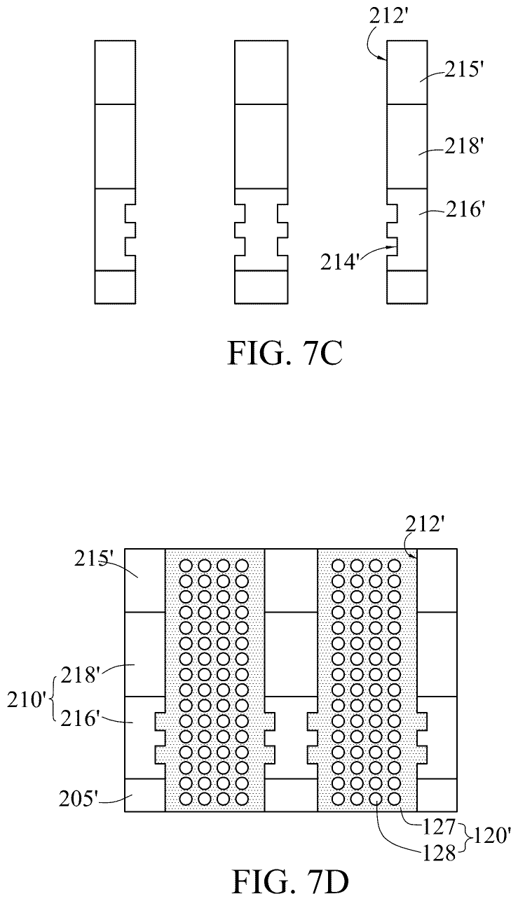

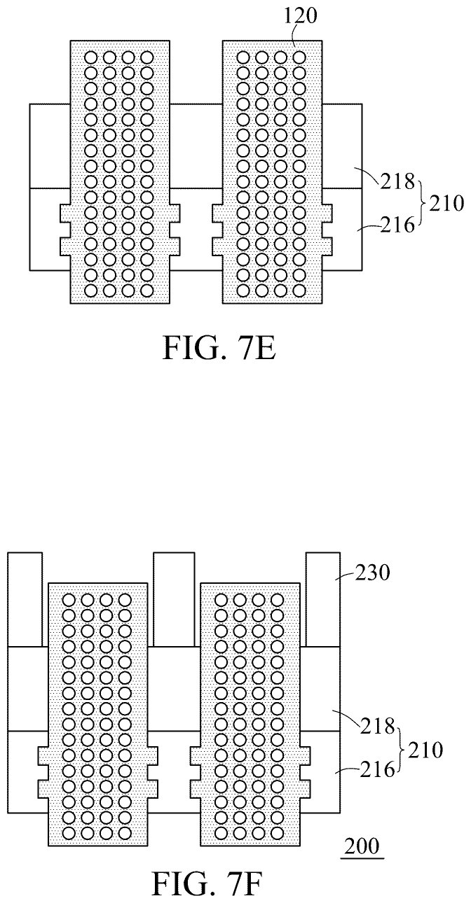

Another embodiment, the manufacturing process for test socket 200 will be described, referring back to FIG. 3 and FIGS. 6 and 7A-7F simultaneously. The manufacturing process of test socket 200 involves several steps. Initially, as shown in step S210 and FIG. 7A, forming a layered structure 200′ comprising a first sacrificial layer. This layered structure 200′ comprises a first sacrificial layer 205′, an insulating support layer 210′, and a second sacrificial layer 215′. The first and second sacrificial layers 205′, 215′ serve as temporary structures. The materials for the first sacrificial layer 205′ and the second sacrificial layer 215′ are similar or identical to the previous examples and will not be reiterated here. Additionally, the insulating support layer 210′ comprises a hard support layer 216′ and a soft support layer 218′, with the soft support layer 218′ positioned above the hard support layer 216′.

Next, step S220 is executed. As illustrated in FIG. 7B, forming a plurality of through-holes 212′ in the layered structure 200′f. The creation of these through-holes 212′ is similar or identical to the method described for making through-holes 112.

Next, step S230 (as shown in FIG. 7C), forming a plurality of grooves 214′ within the through-holes 212′ of the insulating support layer 216′, particularly around the boundaries of the through-holes 212′.

Next, step S240 (as shown in FIG. 7D), filling the through-holes 212′ and grooves with a conductive gel 120′ to form a plurality of conductive columns. This conductive gel 120′, consisting of conductive particles 127 and a flexible material 128, solidifies to form the conductive columns 120. The conductive columns 120 extend through the through-holes 212′, with the protruding parts, embedded in the grooves 214′ of the insulating support layer.

Next, step S250 (as shown in FIG. 7E), removing the first and second sacrificial layers 205′ and 215′. This removal methods is similar or identical to the removal methods of sacrificial layers 105′ and 205′ . . . . Removing the first sacrificial layer 205′ and the second sacrificial layer 215′ exposes the conductive columns 120 and the insulating support layer 210, which comprises the hard support 216 and the soft support 218, thus completing the main part of test socket 200.

Next, step S260 (as shown in FIG. 7F), Place anti-short-circuit brackets 230 Adjacent to the Second Part of the Conductive Columns 120. These anti-short-circuit brackets 230 are made of insulating material and serve to prevent the conductive columns 120 from contacting each other and causing a short circuit.

Furthermore, in certain embodiments, the hard support layer 216′ of the insulating support structure 210′ or insulating support layer 110 comprises multiple layers of different compositions or materials. These materials are chosen based on their etch selectivity. When the hard support layer 216′ or undergoes an etching process to form grooves 214′, layers with lower etch selectivity are etched faster than those with higher etch selectivity. This etching rates variation allows grooves 214′ to be formatted in desired areas of the hard support layer 216′.

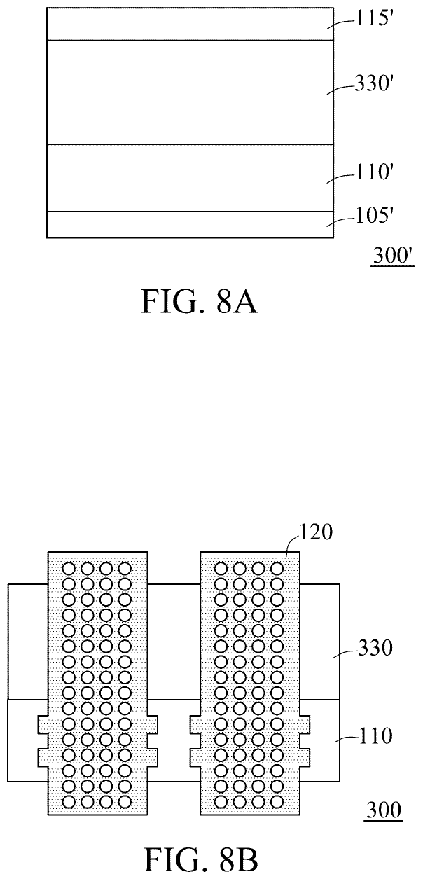

Additionally, in some embodiments, as shown in FIG. 8A, the layered structure 300′ comprises a first sacrificial layer 105′, an anti-short-circuit bracket layer 330′, an insulating support layer 110′, and a second sacrificial layer 115′. Here, the anti-short-circuit bracket layer 330′ serves as the parent material for the anti-short-circuit brackets 330. After the layered structure 300′ undergoes steps similar to those described in S220-S250, a test socket 300 as shown in FIG. 8B is formed. The advantage of this design is that the anti-short-circuit brackets 330 can be directly formed during the manufacturing process, improving process efficiency. As a result, compared to test socket 200, the anti-short-circuit brackets 330 in test socket 300 are tightly connected to the conductive columns 120 without any gaps.

The materials of the various components of test sockets 100, 200, 300, including the insulating support structures, conductive columns, and anti-short-circuit brackets, are carefully chosen to optimize the performance and durability of test sockets 100, 200, 300. For example, the hard support 216 of the insulating support structure 210 or insulating support structure 110 is made from materials selected from the group of polyimide, PCB materials, and ceramic materials. Each of these materials possesses specific properties that contribute to the overall performance of the test socket.

Furthermore, the conductive columns 120 provide electrical connectivity for IC testing and are composed of conductive particles 127 and a flexible material 128. The conductive particles 127 can be selected from a group of materials including metal powder, metal alloy powder, graphite powder, conductive compounds, and conductive plastics. The choice of materials for conductive particles 127 influences the conductivity and durability of the conductive columns 120. The flexible material 128, such as silicone, provides elasticity, enabling the conductive columns 120 to accommodate variations due to warpage of the IC packaging and tolerances in the size of BGA solder balls.

Additionally, the anti-short-circuit brackets 230, 330 located beside the conductive columns 120 are made from insulating materials. These materials are chosen for their high insulating properties, effectively preventing the conductive columns 120 from contacting each other and causing a short circuit. The choice of materials for the anti-short-circuit brackets 230, 330 enhances the safety and reliability of test sockets 200, 300 during IC testing. Potential materials for anti-short-circuit brackets 230, 330 include:
1. Plastics, such as polyvinyl chloride or polyethylene terephthalate;
2. Ceramics;
3. Composite materials, such as glass fiber or carbon fiber composites;
4. Insulating polymers, such as polyimide or polytetrafluoroethylene (Teflon).

Overall, the present invention provides several advantages over traditional IC test sockets. One advantage of the invention is the grooves structure in the insulating support structure, located next to the through-holes. These grooves, enhancing the Fixation strength of the conductive columns to the insulating support structure. Thus the lifetime of the test socket and the stability of the electrical connections during testing are increased. Additionally, the test socket can also adding anti-short-circuit brackets located next to the conductive columns, reducing the risk of short circuits during testing. This feature enhances the safety and reliability of the test socket, making it a robust solution for IC testing. Moreover, the use of hard and soft supports in the insulating support structure provides a sturdy yet flexible frame for the conductive columns. This composite structure reduced the likelihood of the conductive columns detaching from the support structure during testing. Furthermore, the composite structure also helps to improve the overall durability and lifetime of the test socket, making it a reliable and cost-effective solution for IC testing.

Although the present invention has been disclosed above in terms of preferred embodiments, they are not intended to limit the present invention. Anyone with ordinary skill in the art may make slight changes and modifications without departing from the spirit and scope of the present invention. Therefore, the scope of protection of the present invention shall be determined by the appended patent application scope.

1. A test socket for integrated circuit (IC) testing, comprising:
an insulating support structure comprising a plurality of through-holes; and
a plurality of conductive columns embedded within the insulating support structure and extending through the through-holes, each conductive column comprising a first part located below the insulating support structure and a second part located above the insulating support structure;
wherein the insulating support structure further comprises a plurality of grooves adjacent to the through-holes, portions of the conductive columns being embedded within these grooves.

2. The test socket of claim 1, wherein the insulating support structure comprises a hard support and a soft support, the soft support located on the upper surface of the hard support, and the hardness of the hard support is greater than that of the conductive columns.

3. The test socket of claim 2, wherein the hard support comprises a plurality of layers composed of different materials.

4. The test socket of claim 2, wherein the grooves are located within the hard support.

5. The test socket of claim 1, further comprising a plurality of anti-short-circuit brackets located adjacent to the conductive columns, wherein the anti-short-circuit brackets are made of insulating material.

6. The test socket of claim 5, wherein the height of the anti-short-circuit brackets is between 0.7 to 4 times the height of the second part of the conductive columns.

7. The test socket of claim 1, wherein the height of the first part ranges from 10 to 100 micrometers.

8. The test socket of claim 1, wherein the height of the second part is 2 to 10 times the height of the first part.

9. The test socket of claim 1, wherein the diameter ratio of the first part to the second part ranges from 5/6 to 6/5.

10. The test socket of claim 1, wherein the insulating support structure is made of materials selected from a group consisting of polyimide, PCB materials, and ceramic materials.

11. The test socket of claim 1, wherein the conductive columns comprise conductive particles and silicone.

12. The test socket of claim 11, wherein the conductive particles are selected from a group consisting of metal powders, metal alloy powders, graphite powders, conductive compounds, and conductive plastics.

13. A method for manufacturing a test socket for integrated circuit (IC) testing, the method comprising:
forming a layered structure comprising a first sacrificial layer, an insulating support layer, and a second sacrificial layer;
forming a plurality of through-holes in the layered structure;
forming a plurality of grooves within the through-holes of the insulating support layer;
filling the through-holes and grooves with a conductive gel to form a plurality of conductive columns; and
removing the first and second sacrificial layers.

14. The method of claim 13, further comprising placing at least one anti-short-circuit bracket adjacent to the conductive columns.

15. The method of claim 13, wherein forming the insulating support layer comprises forming a hard support layer and a soft support layer, the soft support layer being located above the hard support layer.

16. A manufacturing method for a test socket for IC testing, the method comprising:
forming a layered structure comprising a first sacrificial layer, an insulating support layer, an anti-short circuit layer, and a second sacrificial layer;
forming a plurality of through-holes in the layered structure;
forming a plurality of grooves within the through-holes of the insulating support layer;
filling the through-holes and grooves with a conductive gel to form a plurality of conductive columns; and
removing the first and second sacrificial layers.

17. The method of claim 16, wherein forming the insulating support layer comprises forming a hard support layer and a soft support layer, the soft support layer being located above the hard support layer.

18. The method of claim 17, wherein forming the hard support layer comprises forming a plurality of layers composed of different materials.
